(19) United States
(12) Patent Application Publication
(10) Pub. No.: US 2024/0334653 A1
(43) Pub. Date: Oct. 3, 2024

(54) COOLING DEVICE FOR OPTICAL ENGINE

(71) Applicant: Young Optics Inc., Hsinchu Science Park (TW)

(72) Inventors: ENG-SENG TAN, Hsinchu Science Park (TW); CHANG-CHUN CHEN, Hsinchu Science Park (TW)

(21) Appl. No.: 18/592,962

(22) Filed: Mar. 1, 2024

(30) Foreign Application Priority Data
Mar. 30, 2023 (TW) 112112384

(51) Int. Cl. H05K 7/20; F25B 21/02

(52) U.S. Cl. CPC H05K 7/2039; F25B 21/02; F25B 2321/0212

(57) ABSTRACT

A cooling device for an optical engine includes a cooler module, a first temperature/humidity sensor, a second temperature/humidity sensor and a temperature control system. The cooler module includes a cooler, the cooler has a heat-absorbing surface and a heat-dissipating surface, and the heat-absorbing surface is thermally coupled to at least one heat source. The first temperature/humidity sensor is disposed in a position not in contact with the cooler module, and the second temperature/humidity sensor is disposed on the heat-absorbing surface. The temperature control system is capable of receiving a signal from the first temperature/humidity sensor, receiving a signal from the second temperature/humidity sensor, and transmitting a signal to the cooler module.

### CROSS-REFERENCE TO RELATED APPLICATION

This application claims the priority benefit of Taiwan application serial no. 112112384, filed Mar. 30, 2023. The entirety of the above-mentioned patent application is hereby incorporated by reference herein and made a part of this specification.

### BACKGROUND

### Field of the Invention

The invention relates to a cooling device, more particularly to a cooling device for an optical engine.

### Description of the Related Art

As the brightness performance for projectors continues to increase, traditional cooling methods are no longer able to resolve the issue of heat accumulation in projectors. To resolve heat dissipation challenges in projectors, modern designs now incorporate thermoelectric coolers (TEC) and use cooling control methods such as described in the following. Specifically, a temperature sensor may be placed on a thermoelectric cooler's cold side to maintain the temperature at the cold side below ambient levels. Alternatively, a humidity sensor may be placed on the thermoelectric cooler's cold side, and the relative humidity around the cold side is regulated to prevent condensation. However, these methods may fail to avoid condensation in unstable temperature/humid conditions or in extreme environmental conditions (such as high temperature/high humidity or low temperature/low humidity). Besides, because the temperature/humidity sensors are installed on the thermoelectric cooler to thus placed deeply inside a projector, the entire cooling device must be disassembled when the temperature/humidity sensors fail and need to be repaired, therefore making it difficult to maintain and replace parts.

### BRIEF SUMMARY OF THE INVENTION

In order to achieve one or a portion of or all of the objects or other objects, one embodiment of the invention provides a cooling device for an optical engine having at least one heat source. The cooling device includes a cooler module, a first temperature/humidity sensor, a second temperature/humidity sensor and a temperature control system. The cooler module includes a cooler, the cooler has a heat-absorbing surface and a heat-dissipating surface, and the heat-absorbing surface is thermally coupled to the at least one heat source. The first temperature/humidity sensor is disposed in a position not in contact with the cooler module, and the second temperature/humidity sensor is disposed on the heat-absorbing surface. The temperature control system is capable of receiving a signal from the first temperature/humidity sensor, receiving a signal from the second temperature/humidity sensor, and transmitting a signal to the cooler module.

Another embodiment of the invention provides a cooling device for an optical engine having at least one heat source. The cooling device includes a cooler module, a temperature/humidity sensor, a temperature sensor and a temperature control system. The cooler module is thermally coupled to the at least one heat source, the temperature/humidity sensor is disposed in a position not in contact with the cooler module, and the temperature sensor is disposed on the cooler module. The temperature control system is electrically connected to the temperature/humidity sensor, the temperature sensor, and the cooler module.

According to the above embodiments, because the first temperature/humidity sensor is arranged externally to and not in contact with the cooler module, the environmental dew point determined by the temperature and humidity readings from the first temperature/humidity sensor may serve as a reference for regulating the power or efficiency of the cooler module. This arrangement may prevent condensation even under extreme or unstable temperature/humidity conditions. Furthermore, due to the external placement of the first temperature/humidity sensor, maintenance or replacement operations of components can be simplified. Additionally, the synergistic integration of the first temperature/humidity sensor outside the cooler module with the second temperature/humidity sensor (or a temperature sensor) on the cooler module enables the temperature control system to automatically adjust or permit the user to choose a suitable control scheme in response to sensor malfunctions. This allows to adjust the power or efficiency of the cooler module to ensure that the projector is free from internal condensation even in scenarios of sensor failure, and allows for a wide temperature modulation span of the cooler module without causing condensation.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram of a cooling device for an optical engine according to an embodiment of the invention.

FIG. 2 shows a schematic diagram of a cooler module according to an embodiment of the invention.

FIG. 3 is a flow chart illustrating a thermal control method for sensor malfunctions according to an embodiment of the invention.

FIG. 4 shows a schematic diagram of a temperature/humidity sensor according to an embodiment of the invention.

### DETAILED DESCRIPTION OF THE INVENTION

In the following detailed description of the preferred embodiments, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. Further, “First,” “Second,” etc, as used herein, are used as labels for nouns that they precede, and do not imply any type of ordering (e.g., spatial, temporal, logical, etc.).

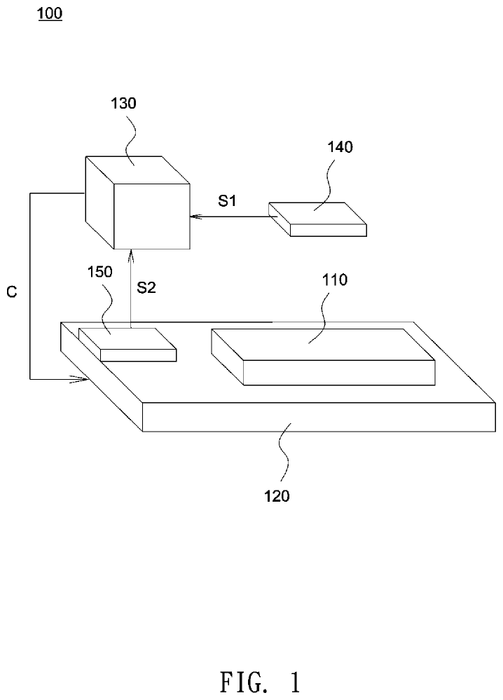

FIG. 1 shows a schematic diagram of a cooling device for an optical engine according to an embodiment of the invention. Referring to FIG. 1, in this embodiment, an optical engine (not shown) includes at least one heat source 110, and the cooling device 100 includes a cooler module 120, a temperature control system 130, a first temperature/humidity sensor 140, and a second temperature/humidity sensor 150. The heat source 110 can be any heat-generating component producing considerable heat in an optical engine. For example, the heat source 110 may be a light-emitting diode (LED) or a DMD (digital micro-mirror device) chip of an optical engine. The cooler module 120 is thermally coupled to the heat source 110 of the optical engine. As used herein, the term “thermally coupled” is defined as heat exchange occurring between two or more components that touch each other or have an indirect connection. More straightforwardly, it involves the movement of thermal energy from a region of higher temperature to one of lower temperature due to temperature differences between these components, and a conductive medium, such as a solid or a fluid, may be provided to facilitate the heat transfer. Moreover, it should be noted that an “optical engine” is commonly recognized and utilized in the field of optical projection technology. Given that an optical engine's function and construction are well-known to those with ordinary skills in the art, the specification omits the description of an optical engine for brevity. The temperature control system 130 is electrically connected to the first temperature/humidity sensor 140, the second temperature/humidity sensor 150, and the cooler module 120. The first temperature/humidity sensor 140 is disposed externally to and not in contact with the cooler module 120, such as being placed on an inner wall of a projector's casing. The first temperature/humidity sensor 140 is of detecting the temperature and humidity of ambient air around the cooler module 120. The second temperature/humidity sensor 150 is disposed on the cooler module 120 to detect the temperature of a cold side of the cooler module 120, where the cold side receives heat conducted from the heat source 110. The external first temperature/humidity sensor 140 detects the temperature and humidity of the air flowing into the vicinity of the cooler module 120 and then sends a temperature/humidity signal S1 to the temperature control system 130. The second temperature/humidity sensor 150 detects the temperature and humidity at the cold side of the cooler module 120 and then transmits the temperature/humidity signal S2 to the temperature control system 130. The temperature control system 130 calculates the air's dew point according to the temperature/humidity signal S1 and compares the dew point with the temperature detected from the second temperature/humidity sensor 150. This comparison helps to determine whether the temperature measured at the cold side of the cooler module 120 falls below the air's dew point to cause condensation. Then, a control signal C based on the comparison result is output to adjust the power or cooling efficiency of the cooler module 120, thus ensuring that the temperature of the cold side remains above the dew point to prevent condensation and allowing for a wide temperature modulation span of the cooler module 120 without causing condensation.

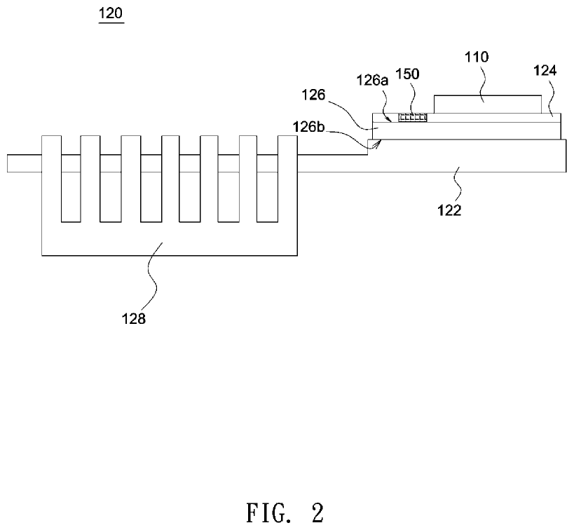

FIG. 2 shows a schematic diagram of a cooler module according to an embodiment of the invention. As shown in FIG. 2, the cooler module 120 includes a base 122, a thermal block 124 for conducting heat, a cooler 126, and a heat dissipation component such as a heat sink 128. The heat sink 128 is thermally coupled to the base 122, and the cooler 126 is disposed between the base 122 and the thermal block 124. The cooler 126 includes a heat-absorbing surface 126a and a heat-dissipating surface 126b, the heat-absorbing surface 126a is thermally coupled to the thermal block 124 to form a cold side of the cooler module 120, and the heat-dissipating surface 126b is thermally coupled with the base 122 and the heat sink 128. In this embodiment, the heat source 110 is disposed on the thermal block 124 of the cooler module 120, and the second temperature/humidity sensor 150 is disposed on the heat-absorbing surface 126a of the cooler 126. The second temperature/humidity sensor 150 may be in direct contact with the thermal block 124 and/or the heat-absorbing surface 126a. The shape of the thermal block 124 is not restricted. In instances where the surface area of the heat source 110 differs from that of the cooler 126, the thermal block 124 may function to evenly distribute the heat produced by the heat source 110 across the cooler 126. In other embodiment, the thermal block 124 may be omitted from the cooler module 120, and the second temperature/humidity sensor 150 may directly touch the heat source 110. In at least some embodiments, the cooler 126 may be a thermoelectric cooler (TEC) or a water-cooled cooler, but the invention is not limited thereto. The heat source 110 may include, for example, at least one of an LED, a laser diode, and a DMD chip in a projector, but the invention is not limited thereto. In at least some embodiments, the cooler 126 includes a thermoelectric chip that uses semiconductor technology to achieve cooling, heating, and temperature regulation by controlling direct currents. The thermoelectric chip contains n-type and p-type semiconductors. When a direct current flows through the thermoelectric chip, the direct current moves from the n-type to the p-type semiconductor to absorbing heat and thus form the heat-absorbing surface 126a, and the direct current moves from the p-type to the n-type semiconductor to release heat and thus form the heat-dissipating surface 126b. Through the design of the above embodiments, the first temperature/humidity sensor 140 can detect the temperature and relative humidity of the environment and feedback to the temperature control system 130 to calculate a dew point of the environment. The second temperature/humidity sensor 150 can detect the temperature of the heat-absorbing surface 126a and feedback to the temperature control system 130. The temperature control system 130 can regulate the temperature of the heat-absorbing surface 126a to ensure this temperature measured at the cold side remains above the dew point to effectively prevent condensation inside a projector.

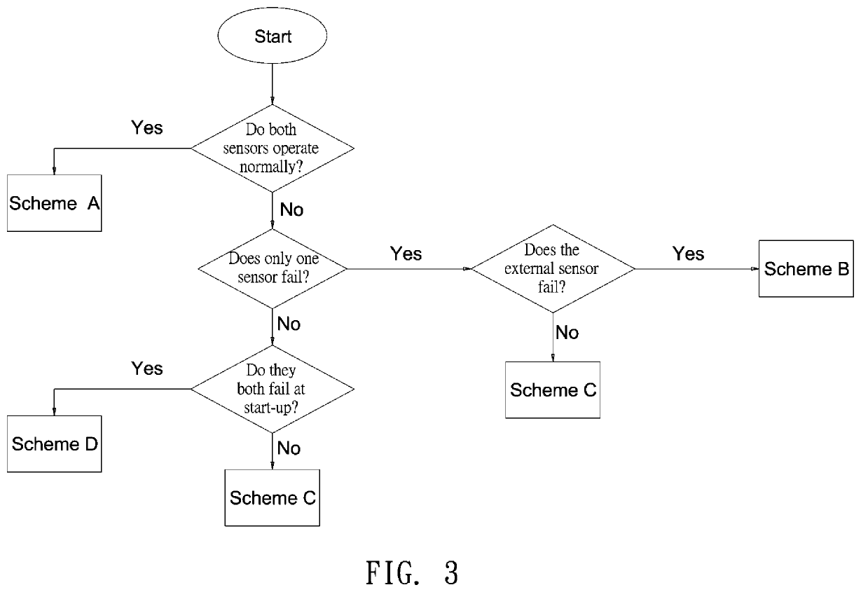

Furthermore, in the above embodiments, using both of the first temperature/humidity sensor 140 (external sensor) and the second temperature/humidity sensor 150 (internal sensor) allows for the implementation of a heat dissipation control method (depicted in FIG. 3) that is designed in conjunction with the characteristics of the cooling system and tailored to the operation states of the two temperature/humidity sensors. As shown in FIG. 3, the first step is to determine whether both temperature and humidity sensors operate normally. If both operate normally, a dew point control method (Scheme A) is implemented: The first temperature/humidity sensor 140 detects the ambient temperature and relative humidity and transmits this data to the temperature control system 130 to calculate the environmental dew point, and the second temperature/humidity sensor 150 detects the temperature at the cold side of the cooler 126 and transmits this data to the temperature control system 130. Then, based on these data, the temperature control system 130 regulates the temperature at the cold side of the cooler 126 to ensure this temperate remains higher than the dew point to effectively prevent condensation. Next, if the first temperature/humidity sensor 140 (external sensor) fails but the second temperature/humidity sensor 150 (internal sensor) operates normally, a humidity control method (Scheme B) is implemented: The second temperature/humidity sensor 150 detects the relative humidity around the heat-absorption surface 126a (i.e., the cold side) of the cooler 126. If the relative humidity is below 90%, the temperature control system 130 enhances the power of the cooler 126; conversely, if the relative humidity is 90% or higher, the temperature control system 130 reduces the power of the cooler 126 to prevent condensation. In comparison, if the second temperature/humidity sensor 150 (internal sensor) fails and thus cannot detect the temperature of the heat-absorption surface 126a, but the first temperature/humidity sensor 140 (external sensor) operates normally, a heat source control method (Scheme C) is implemented: For instance, the power of the cooler 126 can be reduced to prevent condensation, such as lowering its cooling efficiency to 80% of the efficiency prescribed in Scheme A. Additionally, under the scenario where the first temperature/humidity sensor 140 and the second temperature/humidity sensor 150 both fail, the system implements a specific control strategy to manage the cooling process. Specifically, if both sensors simultaneously fail after operating for a period, the same heat source control method (Scheme C) is applicable. However, if both sensors are identified as malfunctioning at the system's start-up, the heat source control method remains applicable but should prioritize preventing condensation inside the projector. In this scenario, the cooler 126 operates at its minimal power or cooling efficiency (Scheme D) to effectively prevent condensation. In at least some embodiments of the invention, the operational status of both temperature/humidity sensors is monitored in real-time throughout the projector's operation. In the event of a malfunction, the system may produce error messages to notify the user. Simultaneously, the system may either automatically adjust or permit the user to choose a suitable control scheme relevant to the fault condition, thereby ensuring the projector operates without any condensation issues.

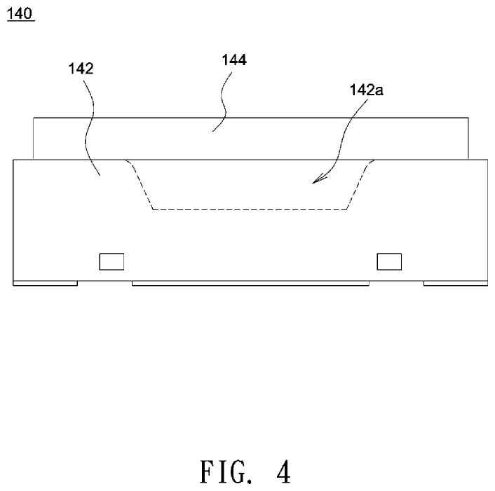

FIG. 4 shows a schematic diagram of a temperature/humidity sensor according to an embodiment of the invention. In this embodiment, a first temperature/humidity sensor 140 includes a component layer 142 and a thin film 144 overlaying the component layer 142, and the thin film 144 may cover a recess 142a formed on the top of the component layer 142. The thin film 144 is composed of either one or any combination of polyurethane methacrylate, polytetrafluoroethylene, polyvinyl chloride and Teflon. Moreover, the second temperature/humidity sensor 150 may possess the same structure analogous to the first temperature/humidity sensor 140.

In various embodiments of the invention described in the above, the second temperature/humidity sensor 150 disposed on the cooler module 120 can be replaced with a temperature sensor dedicated solely to temperature measurement. This alternative temperature sensor is also allowed to detect the cold side temperature of the cooler module 120 and transmit the detected temperature values to the temperature control system 130. Further, where necessary, multiple second temperature/humidity sensors 150 can be provided. For instance, in case the heat source 110 has large surface areas, multiple second temperature/humidity sensors 150 may spread over different regions of the heat source 110 to accurately detect the temperature of each region of the heat source 110.

According to the above embodiments, because the first temperature/humidity sensor is arranged externally to and not in contact with the cooler module, the environmental dew point determined by the temperature and humidity readings from the first temperature/humidity sensor may serve as a reference for regulating the power or efficiency of the cooler module. This arrangement may prevent condensation even under extreme or unstable temperature/humidity conditions. Furthermore, due to the external placement of the first temperature/humidity sensor, maintenance or replacement operations of components can be simplified. Additionally, the synergistic integration of the first temperature/humidity sensor outside the cooler module with the second temperature/humidity sensor (or a temperature sensor) on the cooler module enables the temperature control system to automatically adjust or permit the user to choose a suitable control scheme in response to sensor malfunctions. This allows to adjust the power or efficiency of the cooler module to ensure that the projector is free from internal condensation even in scenarios of sensor failure, and allows for a wide temperature modulation span of the cooler module without causing condensation.

Though the embodiments of the invention have been presented for purposes of illustration and description, they are not intended to be exhaustive or to limit the invention. Accordingly, many modifications and variations without departing from the spirit of the invention or essential characteristics thereof will be apparent to practitioners skilled in this art. It is intended that the scope of the invention be defined by the claims appended hereto and their equivalents in which all terms are meant in their broadest reasonable sense unless otherwise indicated.

What is claimed is:

1. A cooling device for an optical engine having at least one heat source, comprising:
a cooler module comprising a cooler, the cooler having a heat-absorbing surface and a heat-dissipating surface, and the heat-absorbing surface being thermally coupled to the at least one heat source;
a first temperature/humidity sensor disposed in a position not in contact with the cooler module;
a second temperature/humidity sensor disposed on the heat-absorbing surface; and
a temperature control system capable of receiving a signal from the first temperature/humidity sensor, receiving a signal from the second temperature/humidity sensor, and transmitting a signal to the cooler module.

2. The cooling device as claimed in claim 1, wherein the cooler module further comprises a base and a thermal block, and the cooler is disposed between the base and the thermal block.

3. The cooling device as claimed in claim 2, wherein the cooler module further comprises a heat sink, and the heat sink is thermally coupled to the base.

4. The cooling device as claimed in claim 1, wherein the second temperature/humidity sensor is configured to detect a relative humidity around the heat-absorption surface if the first temperature/humidity sensor fails, and the temperature control system is capable of adjusting a power of the cooler according to the relative humidity detected by the second temperature/humidity sensor.

5. The cooling device as claimed in claim 1, wherein the temperature control system is configured to reduce a cooling efficiency of the cooler if the second temperature/humidity sensor fails.

6. The cooling device as claimed in claim 1, wherein the first temperature/humidity sensor is capable of detecting an ambient temperature and a relative humidity of environment and transmitting the detected ambient temperature and the relative humidity to the temperature control system, the temperature control system is capable of calculating a dew point of the environment based on the ambient temperature and the relative humidity, the second temperature/humidity sensor is capable of detecting a temperature of the heat-absorbing surface and transmitting the detected temperature to the temperature control system, and the temperature control system is capable of regulating the temperature of the heat-absorbing surface to ensure the temperature of the heat-absorbing surface is higher than the dew point.

7. The cooling device as claimed in claim 1, wherein the heat source comprises at least one of a light-emitting diode, a laser diode and a digital micro-mirror chip.

8. The cooling device as claimed in claim 1, wherein each of the first temperature/humidity sensor and the second temperature/humidity sensor comprises a thin film and a component layer having a recess, and the thin film overlays the recess of the component layer.

9. The cooling device as claimed in claim 8, wherein the thin film is composed of either one or any combination of polyurethane methacrylate, polytetrafluoroethylene, polyvinyl chloride, and Teflon.

10. A cooling device for an optical engine having at least one heat source, comprising:
a cooler module thermally coupled to the at least one heat source;
a temperature/humidity sensor disposed in a position not in contact with the cooler module;
a temperature sensor disposed on the cooler module; and
a temperature control system electrically connected to the temperature/humidity sensor, the temperature sensor and the cooler module.

11. The cooling device as claimed in claim 10, wherein the cooler module comprises a cooler having a heat-absorbing surface and a heat-dissipating surface.

12. The cooling device as claimed in claim 11, wherein the cooler module further comprises a base and a thermal block, and the cooler is disposed between the base and the thermal block.

13. The cooling device as claimed in claim 12, wherein the cooler module further comprises a heat sink, and the heat sink is thermally coupled to the base.

14. The cooling device as claimed in claim 11, wherein the temperature/humidity sensor is capable of detecting an ambient temperature and a relative humidity of environment and transmitting the detected ambient temperature and the relative humidity to the temperature control system, the temperature control system is capable of calculating a dew point of the environment based on the ambient temperature and the relative humidity, the temperature sensor is capable of detecting a temperature of a heat-absorbing surface of the cooler module and transmits the detected temperature to the temperature control system, and the temperature control system is capable of regulating the temperature of the heat-absorbing surface to ensure the temperature of the heat-absorbing surface is higher than the dew point.

15. The cooling device as claimed in claim 11, wherein the temperature control system is configured to reduce a cooling efficiency of the cooler if the temperature sensor fails.

16. The cooling device as claimed in claim 10, wherein the heat source comprises at least one of a light-emitting diode, a laser diode and a digital micro-mirror chip.

17. The cooling device as claimed in claim 10, wherein the temperature/humidity sensor comprises a thin film and a component layer having a recess, and the thin film overlays the recess of the component layer.

18. The cooling device as claimed in claim 17, wherein a material of the thin film is selected from the group consisting of polyurethane methacrylate, polytetrafluoroethylene, polyvinyl chloride, and Teflon.
